(19) United States
(12) Patent Application Publication
(10) Pub. No.: US 2012/0026563 A1
(43) Pub. Date: Feb. 2, 2012

(54) IMAGE PROCESSING APPARATUS, IMAGE FORMING APPARATUS, AND METHOD FOR IMAGE PROCESSING, CONFIGURED TO DIVIDE AND READ A DOCUMENT TO GENERATE DIVIDED IMAGE DATA

(75) Inventor: Baba Masaki, Osaka (JP)

(73) Assignee: KYOCERA MITA CORPORATION, Osaka (JP)

(21) Appl. No.: 13/193,155

(22) Filed: Jul. 28, 2011

(30) Foreign Application Priority Data
Jul. 28, 2010 (JP) 2010-169277

(51) Int. Cl. G03F 3/08

(52) U.S. Cl. 358/519; 358/518; 358/522

(57) ABSTRACT

An image processing apparatus is configured to divide and read a document to generate divided image data. The image processing apparatus includes an image reading unit, a high-frequency-color identifying unit, an individual-density conversion information generating unit, and a color-component-data converting unit. When the image reading unit divides and reads the document, the high-frequency-color identifying unit detects a density frequency distribution for the entire document and identifies, from a plurality of colors represented by a plurality of pieces of color component data, a high-frequency color that appears in an image of the entire document with a frequency satisfying a predetermined high-frequency condition; the individual-density conversion information generating unit generates individual-density conversion information based on the entire document; and the color-component-data converting unit generates converted color image data based on the entire document.

### INCORPORATION BY REFERENCE

This application is based upon and claims the benefit of priority from the corresponding Japanese Patent application No. 2010-169277, filed Jul. 28, 2010, the entire contents of which is incorporated herein by reference.

### BACKGROUND

The present invention relates to image processing apparatuses, image forming apparatuses, and methods for image processing configured to divide and read a document to generate divided image data.

When an image processing apparatus that is mounted on a scanner, a copier, a facsimile, or a multifunction peripheral reads an image located on a front side of a document having images on both the front and back sides thereof, so-called “show-through” can occur. This is a problem wherein the image on the back side of the document appears in the read image. Since such a “show-through image” is an image on the back side appearing through the document sheet, the density of the image is unlikely to be very great. Therefore, show-through correction is generally performed wherein the overall density of the read image is reduced to make the show-through portion less noticeable. However, this results in a problem because the density of not only the show-through portion, but also of the original image of the read document is reduced.

An image processing apparatus has been proposed as a solution to this problem. The image processing apparatus reads a document, calculates a density histogram (frequency distribution) two-dimensionally representing a relationship between density and frequency based on the density data of the read document, extracts the highest-frequency density data and its neighboring density data, and uniformly converts the densities of pixels having the neighboring density data to the highest-frequency density. Thus, the image processing apparatus replaces pixels of the show-through portion with a background color of the document to reduce the occurrence of show-through.

This is achieved because the background color portion occupies a large area of the entire document and corresponds to highest-frequency density data. Whereas the show-through portion has a lower density and corresponds to pixels of density data close to the highest-frequency density data which is presumed to correspond to the background color portion.

A frequency distribution will now be described. FIG. 8 is an example of a density histogram that represents a relationship between density and frequency. The density histogram is obtained by calculating the frequency of a density occurrence for each predetermined density range in image data. In the example of FIG. 8, densities ranging from 0 to 15 occur with the greatest frequency. In this example, a pixel region having a density within this range can be presumed to be a background, and a region having a density in the range of 16 to 31, which is close to densities ranging from 0 to 15 (that occur with the highest frequency), can be presumed to be the show-through portion.

However, when forming a plurality of images by dividing one document, the proposed technique involves a process in which a plurality of copies are generated from one document and, for each of the copies, pixels of a portion presumed to be the show-through portion are replaced with the background color of the document. In this case, density data with the greatest frequency is extracted for each of the divided copies. Since image data of the undivided entire document is different from image data of each of the divided copies, the density histogram of the undivided entire document is different from the density histogram of each of the divided copies. Therefore, if there is a significant difference in image data between the undivided entire document and each of the divided copies, the density data with the greatest frequency may be totally different between them.

If the density data with the greatest frequency is different as described above, a color that is presumed to be the background color will be different from one copy to another. Accordingly, a show-through region identified as a density close to that of a color presumed to be a background color will be different from one copy to another. It is originally assumed that the show-through regions of the same color appear in backgrounds which are uniform for all copies. However, if the colors of the show-through regions that are different among the divided copies are made the same as different background colors of the divided copies, an overall image with unnatural colors and non-uniformity may be produced.

### SUMMARY

An image processing apparatus according to an embodiment of the present disclosure is configured to divide and read a document to generate divided image data. The image processing apparatus includes an image reading unit, a high-frequency-color identifying unit, an individual-density conversion information generating unit, and a color-component-data converting unit. The image reading unit reads an image of the document as color image data including a plurality of pieces of color component data. The high-frequency-color identifying unit detects a density frequency distribution for the document and identifies, from a plurality of colors represented by the plurality of pieces of color component data, a high-frequency color that appears in the image of the document with a frequency satisfying a predetermined high-frequency condition. The individual-density conversion information generating unit generates, for each high-frequency color identified by the high-frequency-color identifying unit, individual-density conversion information for converting each of the pieces of color component data such that a color that is close to the high-frequency color becomes substantially the same as the high-frequency color. The color-component-data converting unit generates converted color image data by converting, based on the individual-density conversion information generated for the high-frequency color by the individual-density conversion information generating unit, each of the pieces of color component data included in color image data representing the color that is close to the high-frequency color. When the image reading unit divides and reads the document, the high-frequency-color identifying unit detects a density frequency distribution for the entire document and identifies, from a plurality of colors represented by the plurality of pieces of color component data, a high-frequency color that appears in the image of the entire document with a frequency satisfying a predetermined high-frequency condition; the individual-density conversion information generating unit generates the individual-density conversion information based on the entire document; and the color-component-data converting unit generates the converted color image data based on the entire document.

An image forming apparatus according to an embodiment of the present disclosure is configured to divide and read a document to generate divided image data. The image forming apparatus includes an image reading unit, a high-frequency-color identifying unit, an individual-density conversion information generating unit, and a color-component-data converting unit. The image reading unit reads an image of the document as color image data including a plurality of pieces of color component data. The high-frequency-color identifying unit detects a density frequency distribution for the document and identifies, from a plurality of colors represented by the plurality of pieces of color component data, a high-frequency color that appears in the image of the document with a frequency satisfying a predetermined high-frequency condition. The individual-density conversion information generating unit generates, for each high-frequency color identified by the high-frequency-color identifying unit, individual-density conversion information for converting each of the pieces of color component data such that a color that is close to the high-frequency color becomes substantially the same as the high-frequency color. The color-component-data converting unit generates converted color image data by converting, based on the individual-density conversion information generated for the high-frequency color by the individual-density conversion information generating unit, each of the pieces of color component data included in color image data representing the color that is close to the high-frequency color. When the image reading unit divides and reads the document, the high-frequency-color identifying unit detects a density frequency distribution for the entire document and identifies, from a plurality of colors represented by the plurality of pieces of color component data, a high-frequency color that appears in the image of the entire document with a frequency satisfying a predetermined high-frequency condition; the individual-density conversion information generating unit generates the individual-density conversion information based on the entire document; and the color-component-data converting unit generates the converted color image data based on the entire document.

A method for image processing according to an embodiment of the present disclosure is configured to divide and read a document to generate divided image data. The image processing method includes image reading, high-frequency-color identifying, individual-density conversion information generating, and color-component-data converting. The image reading reads an image of the document as color image data including a plurality of pieces of color component data. The high-frequency-color identifying detects a density frequency distribution for the document and identifies, from a plurality of colors represented by the plurality of pieces of color component data, a high-frequency color that appears in the image of the document with a frequency satisfying a predetermined high-frequency condition. The individual-density conversion information generating generates, for each high-frequency color identified by the high-frequency-color identifying, individual-density conversion information for converting each of the pieces of color component data such that a color that is close to the high-frequency color becomes substantially the same as the high-frequency color. The color-component-data converting generates converted color image data by converting, based on the individual-density conversion information generated for the high-frequency color by the individual-density conversion information generating, each of the pieces of color component data included in color image data representing the color that is close to the high-frequency color. When the image reading divides and reads the document, the high-frequency-color identifying detects a density frequency distribution for the entire document and identifies, from a plurality of colors represented by the plurality of pieces of color component data, a high-frequency color that appears in the image of the entire document with a frequency satisfying a predetermined high-frequency condition; the individual-density conversion information generating generates the individual-density conversion information based on the entire document; and the color-component-data converting generates the converted color image data based on the entire document.

Additional features and advantages are described herein, and will be apparent from the following Detailed Description and the figures.

### BRIEF DESCRIPTION OF THE FIGURES

FIG. 1 is a block diagram illustrating a general configuration of a multifunction peripheral according to an embodiment of the present disclosure.

FIG. 2 is a block diagram illustrating a configuration of a main part of an image processing unit included in the multifunction peripheral illustrated in FIG. 1.

FIG. 3 is a color histogram.

FIG. 4A to FIG. 4C illustrate a set of density conversion tables generated in density conversion performed by the multifunction peripheral illustrated in FIG. 1.

FIG. 5A to FIG. 5C illustrate another set of density conversion tables generated in density conversion performed by the multifunction peripheral illustrated in FIG. 1.

FIG. 6 is a flowchart illustrating a procedure of density conversion and a procedure of outputting a document performed by the multifunction peripheral illustrated in FIG. 1.

FIG. 7A and FIG. 7B each illustrate a mode of dividing a document.

FIG. 8 is a density histogram.

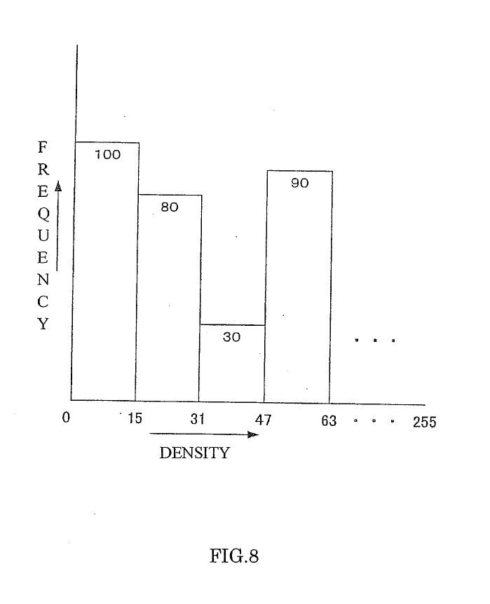

### DETAILED DESCRIPTION

Reference will now be made to various embodiments of the disclosure, one or more examples of which are illustrated in the accompanying drawings. Each example is provided by way of example, and by no way limit the present disclosure. In fact, it will be apparent to those skilled in the art that various modifications, combinations, additions, deletions and variations can be made in the present disclosure without departing from the scope or spirit of the present disclosure. For instance, features illustrated or described as part of one embodiment can be used in another embodiment to yield a still further embodiment. It is intended that the present disclosure covers such modifications, combinations, additions, deletions, applications and variations that come within the scope of the appended claims and their equivalents.

To help understand the present invention, embodiments of the present invention will be described with reference to the attached drawings. Note that the embodiments to be described below are exemplary embodiments of the present invention and are not intended to limit the technical scope of the present invention.

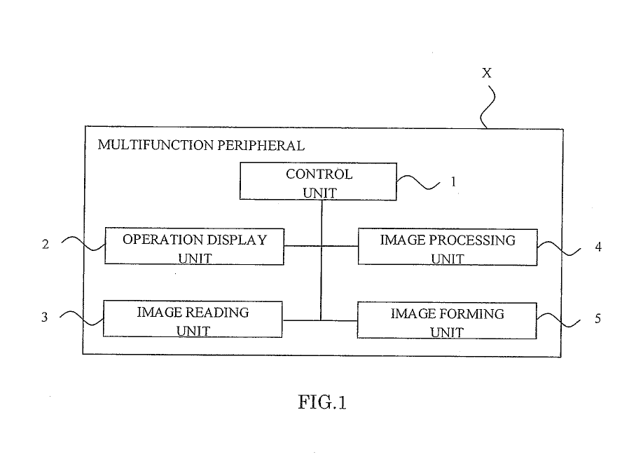

First, with reference to FIG. 1, a general configuration of a multifunction peripheral X according to an embodiment of the present disclosure will be described.

The multifunction peripheral X is an example of an image processing apparatus and an image forming apparatus according to the present disclosure. As illustrated in FIG. 1, the multifunction peripheral X mainly includes a control unit 1, an operation display unit 2, an image reading unit 3, an image processing unit 4, and an image forming unit 5. Copiers and facsimiles also can be used as the image forming apparatus according to the present disclosure. Scanners, copiers, and facsimiles can be used as the image processing apparatus according to the present disclosure.

The control unit 1 includes peripheral devices, such as a central processing unit (CPU), a read-only memory (ROM), and a random-access memory (RAM). The control unit 1 performs overall control of the multifunction peripheral X by having the CPU execute processing in accordance with a predetermined control program stored in the ROM.

The operation display unit 2 includes a liquid-crystal display, a touch panel, and various operation keys for displaying various types of information and allowing a user to perform input operations on the multifunction peripheral X. A button for starting show-through processing and keys for specifying modes of division (described below) are included in the operation display unit 2.

The image reading unit 3 includes a charge-coupled device (CCD) sensor that reads an image of a document placed on a document plate (not shown) or fed by a known automatic document feeder (ADF) (not shown).

The image reading unit 3 reads an image of a document as color image data including color component data of three colors, red (R), green (G), and blue (B) (hereinafter referred to as R color component data, G color component data, and B color component data (or RGB color component data)). The image reading unit 3 reads an image of either a monochrome or color document as color image data including RGB color component data.

The image reading unit 3 includes a contact glass plate for reading a document, and the ADF for automatically conveying a document onto the contact glass plate. The ADF includes a known document size detector that detects the length of a document in the document conveying direction (sub-scanning direction) when a light beam is interrupted by the document fed to a document conveying path. In show-through processing described below, the document size detector detects a size of a document based on the length of the document in the sub-scanning direction.

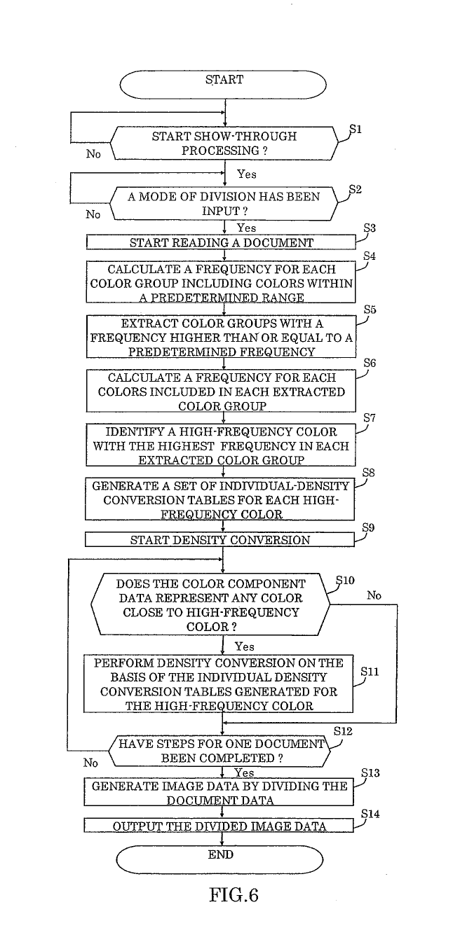

The image processing unit 4 performs various types of image processing on color image data read by the image reading unit 3. Examples of the image processing include dividing a document having a size automatically calculated from a mode (type) of document division input by the operation display unit 2 and the length of the document in the sub-scanning direction detected by the image reading unit 3, calculating a density histogram described below, density conversion described below (see the flowchart of FIG. 6), known gamma correction, shading correction, smoothing and enhancement, and CMYBk conversion. For example, CMYBk conversion involves converting the RGB color component data to color image data including CMYBk color component data.

When the multifunction peripheral X performs copying, the image processing unit 4 outputs the image-processed color image data to the image forming unit 5. When the multifunction peripheral X performs scanning, the image processing unit 4 stores the image-processed color image data in an internal storage unit or transmits it through a network, such as a local area network (LAN), to a predetermined information processing apparatus or the like.

The image forming unit 5 includes constituent components of a known electrophotographic image forming unit, such as photosensitive drums and developing devices. On a sheet fed from a paper feed cassette, the image forming unit 5 forms a monochrome image or a color image based on the color image data inputted from the image processing unit 4.

The multifunction peripheral X features density conversion (see the flowchart of FIG. 6) and division and output processing performed by the image processing unit 4. Hereinafter, means of performing these processes will be described in detail.

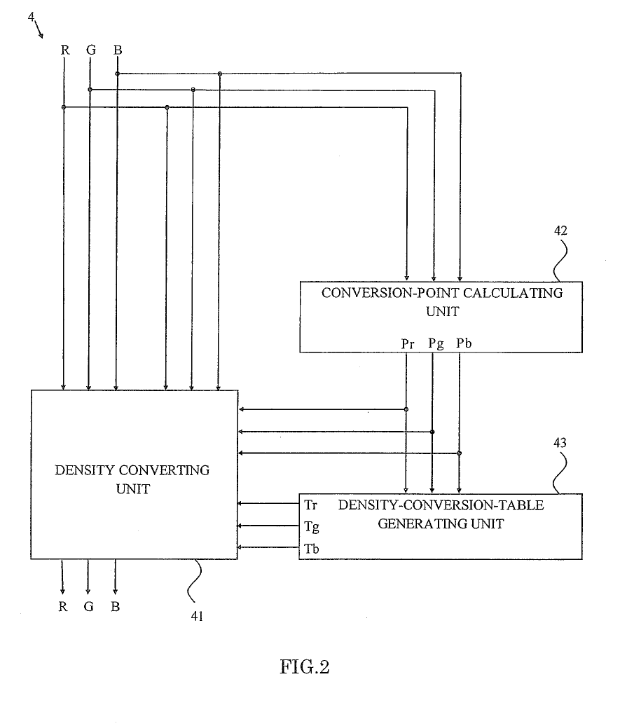

FIG. 2 is a block diagram illustrating the main functions of the image processing unit 4.

As illustrated in FIG. 2, the image processing unit 4 includes a density converting unit 41, a conversion-point calculating unit 42, and a density-conversion-table generating unit 43.

The image processing unit 4 includes other image processing sections that perform various types of image processing, such as gamma correction, shading correction, smoothing and enhancement, and CMYBk conversion, on color image data processed by the density converting unit 41. However, such image processing sections will not be described here, as they are substantially the same as those in the related art.

The density converting unit 41, the conversion-point calculating unit 42, and the density-conversion-table generating unit 43 each may be either an electronic circuit having a function described below or a processing function that is achieved when processing is performed by an arithmetic processing unit such as a microprocessing unit (MPU).

The density converting unit 41 converts, based on a set of predetermined density conversion tables, the RGB color component data included in the color image data read by the image reading unit 3. The density converting unit 41 corresponds to a color-component-data converting unit. Although conversion of RGB color component data will be described in the present embodiment, the same technique is applicable to the case where, for example, after conversion of RGB data to CMY data, each of cyan (C), magenta (M), and yellow (Y) image data is converted.

As described below, the density converting unit 41 converts the RGB color component data for color image data representing a color that is close to a high-frequency color identified by the conversion-point calculating unit 42. As for color image data representing colors that are not close to the high-frequency color, the density converting unit 41 does not convert the RGB color component data.

The conversion-point calculating unit 42 identifies, from a plurality of colors represented by the RGB color component data, a high-frequency color that appears in an image of the entire document with a frequency satisfying a predetermined high-frequency condition. The conversion-point calculating unit 42 corresponds to a high-frequency-color identifying unit.

Then, the conversion-point calculating unit 42 outputs, to the density converting unit 41 and the density-conversion-table generating unit 43, a set of conversion points Pr, Pg, and Pb corresponding to respective density values of the RGB color component data representing the identified high-frequency color.

A technique used by the conversion-point calculating unit 42 to identify a high-frequency color will now be described.

First, when a plurality of colors represented by RGB color component data are divided into color groups each having a predetermined range of colors, the conversion-point calculating unit 42 calculates a first color histogram (three-dimensional histogram) that represents the frequency (or number) of pixels for each of the color groups included in an image of a document. The conversion-point calculating unit 42 that performs this processing corresponds to a first-color-histogram calculating unit.

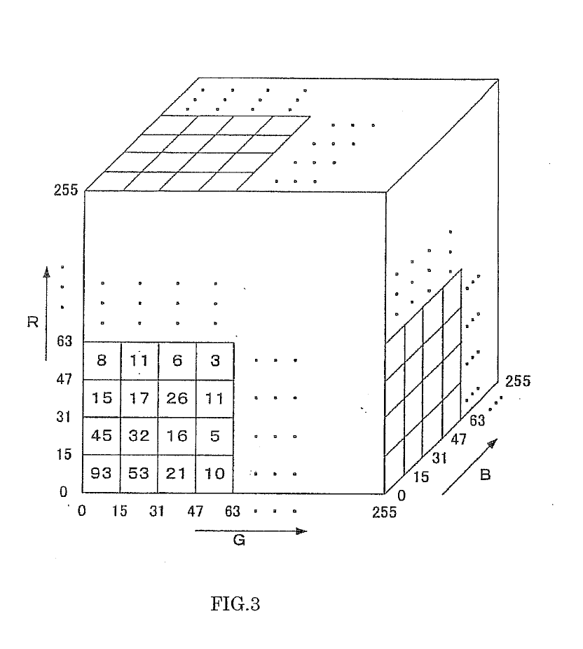

FIG. 3 illustrates an example of the first color histogram.

As illustrated in FIG. 3, the first color histogram is obtained by three-dimensionally arranging density values of RGB color component data included in color image data, and calculating a frequency for each color group that includes colors within a predetermined range defined by three-dimensional density values (R, G, B). Specifically, the first color histogram illustrated in FIG. 3 is obtained by dividing 256×256×256=16777216 colors represented by combinations of values of the respective RGB color component data into 16×16×16=4096 color groups, and then calculating a frequency of pixels for each of the color groups included in an image of a document. In this example, colors within a predetermined range of each of the color groups are as follows: (R, G, B)=(0 to 15, 0 to 15, 0 to 15), (16 to 31, 0 to 15, 0 to 15), (32 to 47, 0 to 15, 0 to 15), . . . , and (239 to 255, 239 to 255, 239 to 255).

Based on the first color histogram, the conversion-point calculating unit 42 extracts, from the color groups described above, a high-frequency color group that appears in an image of a document with a frequency greater than or equal to a predetermined frequency. The conversion-point calculating unit 42 that performs this processing corresponds to a high-frequency-color-group extracting unit. The predetermined frequency is preset, for example, for determining whether a color occupies an area large enough to cause significant show-through in an image of a document.

The conversion-point calculating unit 42 is designed not only to identify a color group with the greatest frequency, but also to extract a high-frequency color group with a frequency greater than or equal to the predetermined frequency. This means that a plurality of high-frequency color groups may be extracted.

That is, with this method, show-through that occurs not only in a region presumed to be the background, but also in a region presumed to be the sub-background that appears very frequently is converted to a sub-background color to correct the show-through.

Then, for each high-frequency color group, the conversion-point calculating unit 42 calculates a second color histogram that represents frequencies of respective colors included in the high-frequency color group. The conversion-point calculating unit 42 that performs this processing corresponds to a second-color-histogram calculating unit.

For example, as illustrated in FIG. 3, when the first color histogram is one that is obtained by dividing 256×256×256=16777216 colors represented by values of RGB color component data into 16×16×16=4096 color groups and calculating a frequency of each color group, the second color histogram is one that is obtained by calculating a frequency of each of 16×16×16=4096 colors included in the color group.

Then, based on the second color histogram, the conversion-point calculating unit 42 identifies a color with the greatest frequency in each high-frequency color group as a high-frequency color that satisfies the high-frequency condition. If a plurality of high-frequency color groups are extracted as described above, a plurality of high-frequency colors are identified here.

A high-frequency density color in the present disclosure is one or more high-frequency colors identified as described above.

As described above, after calculating the first color histogram, which is a rougher histogram, the conversion-point calculating unit 42 extracts one or more color groups with a frequency greater than or equal to a predetermined frequency. Then, for each of only the extracted one or more color groups, the conversion-point calculating unit 42 calculates the second color histogram, which is a more detailed histogram. Therefore, as compared to the case where a histogram representing frequencies of all colors (16777216 colors in the above example) is calculated, the processing load can be significantly reduced.

For each high-frequency color identified by the conversion-point calculating unit 42, the density-conversion-table generating unit 43 generates a set of individual-density conversion tables (an example of individual-density conversion information) that is used to convert the respective RGB color component data such that a color close to the high-frequency color (i.e., a sub-high-frequency density color in the present disclosure) becomes the same or substantially the same as the high-frequency color. The density-conversion-table generating unit 43 outputs the set of individual-density conversion tables to the density converting unit 41. That is, in the present embodiment, when a color close to a background color is converted to the background color, a color close to that of a sub-background (which appears with a high frequency) and presumed to correspond to show-through that occurs in the sub-background is also converted to the color of the sub-background, as described below, to correct the show-through. The density-conversion-table generating unit 43 corresponds to an individual-density conversion information generating unit.

When a plurality of high-frequency colors are identified by the conversion-point calculating unit 42, the density-conversion-table generating unit 43 generates a plurality of sets of individual-density conversion tables Tr, Tg, and Tb corresponding to the respective RGB color component data.

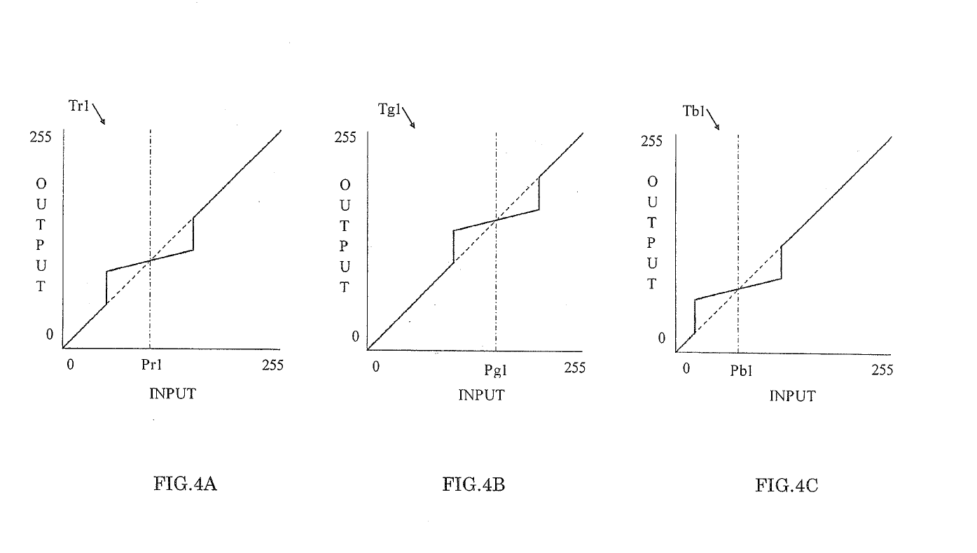

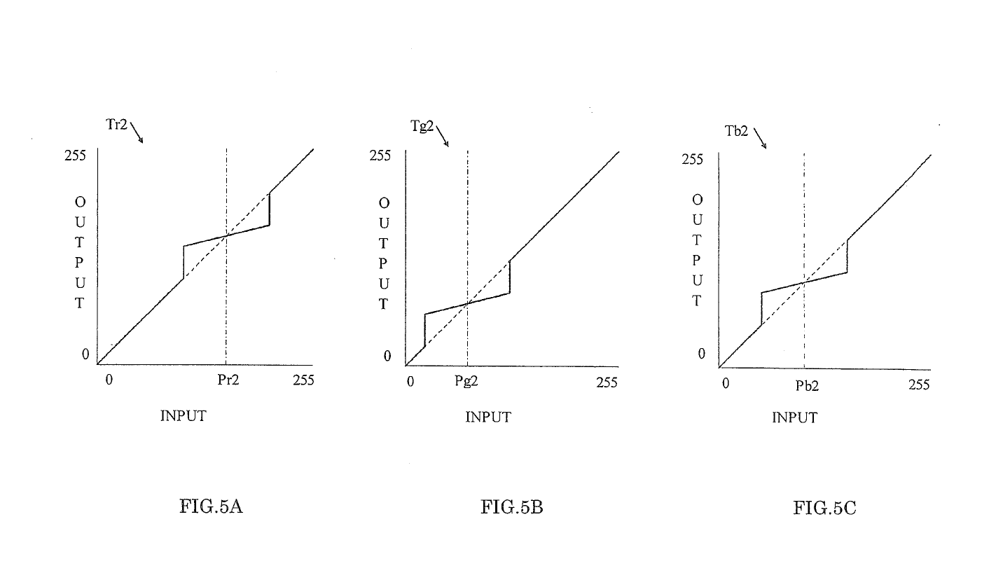

FIG. 4A to FIG. 4C and FIG. 5A to FIG. 5C illustrate an example of individual-density conversion tables generated by the density-conversion-table generating unit 43 when the conversion-point calculating unit 42 identifies two high-frequency colors, a first high-frequency color and a second high-frequency color. The number of individual-density conversion tables generated by the density-conversion-table generating unit 43 varies depending on the number of high-frequency colors identified.

FIG. 4A to FIG. 4C illustrate an example of individual-density conversion tables generated for the first high-frequency color represented by a set of conversion points Pr1, Pg1, and Pb1 which are values of color components R, G, and B, respectively. FIG. 4A to FIG. 4C illustrate a set of individual-density conversion tables Tr1, Tg1, and Tb1 corresponding to respective RGB color component data.

FIG. 5A to FIG. 5C illustrate an example of individual-density conversion tables generated for the second high-frequency color represented by a set of conversion points Pr2, Pg2, and Pb2 which are values of color components R, G, and B, respectively. FIG. 5A to FIG. 5C illustrate a set of individual-density conversion tables Tr2, Tg2, and Tb2 corresponding to respective RGB color component data.

The individual-density conversion table Tr1 illustrated in FIG. 4A is used to convert a sub-high-frequency density color which is a density color within a predetermined range centered on the conversion point Pr1, which is the value of the R color component included in the first high-frequency color, such that the sub-high-frequency density color becomes the same or substantially the same as the conversion point Pr1.

Similarly, the individual-density conversion tables Tg1 and Tb1 illustrated in FIG. 4B and FIG. 4C are used to convert sub-high-frequency density colors which are density colors within corresponding predetermined ranges centered on the respective conversion points Pg1 and Pb1, which are the values of the respective G and B color components included in the first high-frequency color, such that the sub-high-frequency density colors become the same or substantially the same as the corresponding conversion points Pg1 and Pb1. The same applies to the set of individual-density conversion tables Tr2, Tg2, and Tb2 illustrated in FIG. 5A to FIG. 5C.

The density conversion tables are not limited to those illustrated in FIG. 4A to FIG. 4C and FIG. 5A to FIG. 5C, and can include any as long as they can be used to remove (or correct) show-through by a process in which a color close to a high-frequency color is made the same or substantially the same as the high-frequency color and thus a color region corresponding to the show-through becomes the same as a background color.

However, when forming a plurality of images by dividing a document, a known image processing apparatus having a show-through-portion editing function generates a plurality of copies from the document and replaces, for each of the copies, pixels of a portion presumed to be a show-through portion with a background color of the document. Since image data of the undivided entire document is different from image data of each of the divided copies, a density histogram of the undivided entire document is different from a density histogram of each of the divided copies. Therefore, if there is a significant difference in image data between the undivided entire document and each of the divided copies, density data having the greatest frequency may be totally different between them.

If density data with the greatest frequency is different as described above, a color presumed to be a background color will be different from one copy to another. Accordingly, a show-through region identified as a density close to that of a color presumed to be a background color will be different from one copy to another. It is originally supposed that show-through regions of the same color appear in backgrounds which are uniform for all copies. However, if colors of show-through regions that are different between the divided copies are made the same as different background colors of the divided copies, an overall image with unnatural colors and non-uniformity may be output.

Therefore, as described in detail below, in the process of the present disclosure, when a document is to be divided and read, a density frequency distribution is detected for the undivided entire document. Then, based on the detected frequency distribution, a high-frequency color is identified. Next, individual-density conversion information is generated based on the undivided entire document. The individual-density conversion information is used to convert each color component data such that a color close to the high-frequency color becomes substantially the same as the high-frequency color. Then, for color image data representing a color close to the high-frequency color, each color component data is converted to generate converted color image data, by using the individual-density conversion information based on the undivided entire document. Then, by dividing the converted color image data, a plurality of pieces of divided image data are generated, and image processing is performed on each of the plurality of pieces of divided image data.

In the process described above, a uniform highest-frequency density color recognized as a background color is determined for the undivided entire document. Then, a density of a sub-high-frequency density color portion that has a color close to the highest-frequency density color and is presumed to be a show-through portion is made the same as the highest-frequency density to obtain converted color image data, which is then divided to output divided image data. Therefore, it is possible to maintain natural colors and uniformity among divided images.

With reference to the flowchart of FIG. 6, a procedure of density conversion performed by the image processing unit 4 will now be described. Note that S1, S2, etc. in the drawing denote steps of the process performed by the control unit 1.

The density conversion is started when an instruction to perform processing for making a show-through portion the same as a background color (hereinafter simply referred to as show-through processing) is inputted (YES in step S1) using an input unit, such as a button, included in the operation display unit 2.

Upon starting the show-through processing, the control unit 1 determines whether an instruction to divide a read document has been inputted from the operation display unit 2, and whether a mode of division (including a division size) has been inputted from the operation display unit 2. If a user has inputted any mode of division, the mode of division is used. If there is no input that specifies a mode of division, a predetermined division factor (e.g., 50%) is used (step S2). Instead of a division factor, a scaling factor (1 or more) for image enlargement may be input.

The mode of division described above may be inputted in percentage terms such as 200% or 400%, or in a manner such as 2 times or 1.4 times. Alternatively, for example, “A3→A4” or “A4→A6” may be inputted to specify that a standard-size document is to be divided into images of standard size.

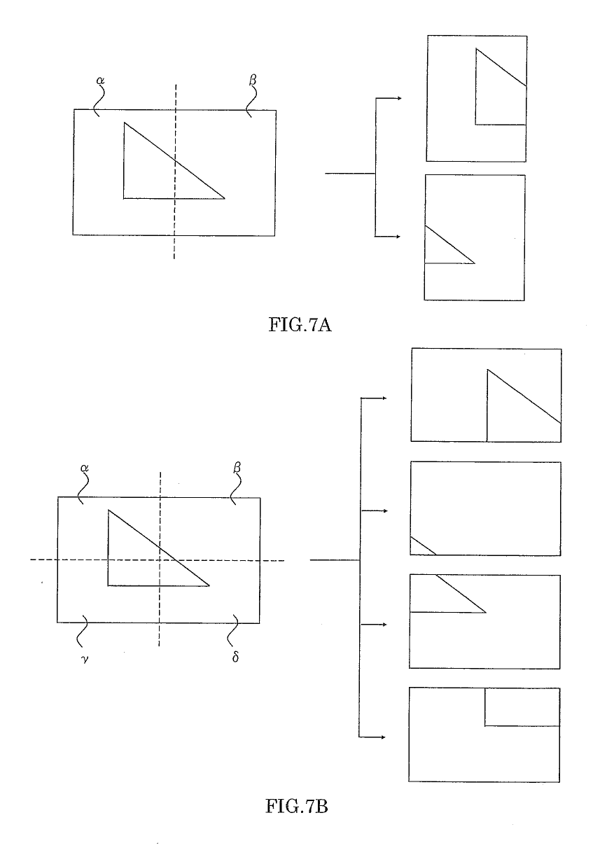

For example, in the case of “A3→A4”, as illustrated in FIG. 7A, one A3 document is divided into two pieces of A4 image data without a change in area, or as illustrated in FIG. 7B, one A3 document is doubled in area (i.e., the length of each side is increased by about 1.4 times) and divided into four pieces of A4 image data.

Such modes of division may be indicated on the operation display unit 2 as symbols which can be selected by the user.

After a mode of division is inputted as described above, the control unit 1 causes the document to be conveyed to the image reading unit 3, and causes the image reading unit 3 to start reading the document (step S3).

After the document is read as described above, color image data is read from the read document image, and RGB color component data included in the color image data is inputted to the image processing unit 4. This causes the image processing unit 4 to start performing show-through processing (step S4).

For example, the control unit 1 or the image processing unit 4 may be configured to select, in accordance with a user operation on the operation display unit 2, whether to perform the density conversion, that is, whether to remove show-through. The predetermined frequency used by the conversion-point calculating unit 42 as a determination index may be preferably changed by the control unit 1 or the image processing unit 4 in accordance with a user operation on the operation display unit 2.

In step S4 to step S7, the conversion-point calculating unit 42 in the image processing unit 4 performs processing to identify a high-frequency color in the document image as described above.

Specifically, as described above, the conversion-point calculating unit 42 calculates the first color histogram by calculating a frequency for each color group including colors within a predetermined range (see FIG. 3) (step S4) and extracts one or more color groups with a frequency greater than or equal to a predetermined frequency on the basis of the first color histogram (step S5). The conversion-point calculating unit 42 then calculates the second color histogram for each extracted color group (step S6) and identifies a high-frequency color with the greatest frequency in each color group (step S7).

In step S8, the density-conversion-table generating unit 43 in the image processing unit 4 generates a set of individual-density conversion tables (see FIG. 4A to FIG. 4C and FIG. 5A to FIG. 5C) for each high-frequency color identified by the conversion-point calculating unit 42, and outputs the individual-density conversion tables to the density converting unit 41.

In step S9, based on the individual-density conversion tables and the conversion points Pr, Pg, and Pb for the RGB color component data representing each high-frequency color input from the conversion-point calculating unit 42, the density converting unit 41 in the image processing unit 4 starts a density conversion of color image data for each pixel of the read document image.

The one or more high-frequency colors described above are an example of a high-frequency density color in the present disclosure.

Specifically, in step S10, the density converting unit 41 determines whether the color image data inputted from the image reading unit 3 is color image data that represents a sub-high-frequency density color which is any color close to the high-frequency color.

If the color image data input from the image reading unit 3 represents any color that is close to the high-frequency color (YES in step S10), the processing proceeds to step S11 (described below). If the color image data input from the image reading unit 3 does not represent any color that is close to the high-frequency color (NO in step S10), the processing proceeds to step S12. For example, as described with reference to FIG. 4A to FIG. 4C and FIG. 5A to FIG. 5C, if color image data of any color that is close to either the high-frequency color represented by the set of conversion points Pr1, Pg1, and P131 or the high-frequency color represented by the set of conversion points Pr2, Pg2, and Pb2 is input (YES in step S10), the processing proceeds to step S11.

Therefore, for color image data which does not represent any color that is close to the high-frequency color, conversion of the RGB color component data based on the individual-density conversion tables in step S11 is not performed. Alternatively, however, density conversion may be performed based on the predetermined conversion tables preset as initial values.

In step S11, for the color image data inputted from the image reading unit 3, the RGB color component data is converted based on the individual-density conversion tables generated for the high-frequency color by the density-conversion-table generating unit 43 in step S8.

For example, if color image data of any color (sub-high-frequency density color) close to the high-frequency color represented by the set of conversion points Pr1, Pg1, and Pb1 illustrated in FIG. 4A to FIG. 4C is inputted, the RGB color component data is converted based on the set of individual-density conversion tables Tr1, Tg1, and Tb1 generated for the high-frequency color in step S8. Similarly, if color image data of any color that is close to the high-frequency color represented by the set of conversion points Pr2, Pg2, and Pb2 illustrated in FIG. 5A to FIG. 5C is inputted, the RGB color component data is converted based on the set of individual-density conversion tables Tr2, Tg2, and Tb2 generated for the high-frequency color in step S8.

Then, the density converting unit 41 determines whether step S10 and step S11 have been completed for the entire color image data of the document read by the image reading unit 3 (step S12). Until these steps for the document are completed (NO in step S12), the processing returns to step S10. If these steps for the document have been completed (YES in step S12), the density conversion for the document ends. Next, image data is generated by dividing the document data in which the density conversion has been completed as described above (step S13).

The document data obtained after the density conversion is divided in accordance with the mode of division input in step S2.

For example, if a mode of division such as that illustrated in FIG. 7A is set in step S2, one A3 document is divided into left and right parts α and β, without a change in area, to form two pieces of A4 image data (step S13). If the multifunction peripheral X performs scanning of each piece of A4 image data, the A4 image data is outputted by temporarily storing it in the storage unit. If the multifunction peripheral X performs copying of each piece of A4 image data, the A4 image data is outputted by forming images on sheets (step S14).

For example, if a mode of division such as that illustrated in FIG. 7B is set in step S2, one A3 document is divided into four parts α to δ, which are enlarged (or doubled in area) to form four divided pieces of A4 image data (step S13). If the multifunction peripheral X performs scanning of each piece of A4 image data, the A4 image data is outputted by temporarily storing it in the storage unit. If the multifunction peripheral X performs copying of each piece of A4 image data, the A4 image data is outputted by forming images on sheets (step S14).

FIG. 7A illustrates a mode of division which involves generating two pieces of image data from one piece of image data, and FIG. 7B illustrates another mode of division which involves generating four pieces of image data from one piece of image data. However, the mode of division is not limited to generating a plurality of pieces of image data from one piece of image data. Instead, only one piece of image data may be generated from one piece of image data. For example, in FIG. 7A, only the left part α may be selectively extracted to form A4-size data. Also, in FIG. 7B, only the upper-left part α may be selectively enlarged to form A4-size data.

As described above, the image processing unit 4 performs various types of image processing, such as gamma correction, shading correction, smoothing and enhancement, and CMYBk conversion, on color image data on which density conversion has been performed.

The density conversion of the present embodiment (see FIG. 6) has been described as one that is performed independent of the gamma correction in the image processing unit 4. Alternatively, the gamma correction may be performed as part of the density conversion.

In the latter case, for each high-frequency color, the density-conversion-table generating unit 43 generates a set of individual gamma tables (an example of individual-density conversion information) corresponding to the RGB color component data and outputs the individual gamma tables to the density converting unit 41. Like the individual-density conversion tables described above (see FIG. 4A to FIG. 4C and FIG. 5A to FIG. 5C), the individual gamma tables generated by the density-conversion-table generating unit 43 realize input-output characteristics that can make colors that are close to the high-frequency color substantially the same as the high-frequency color.

Then, for color image data that represents any color that is close to the high-frequency color, the density converting unit 41 performs gamma correction on each of the pieces of the RGB color component data included in the color image data based on the individual gamma tables generated by the density-conversion-table generating unit 43. For color image data that represents other colors, the density converting unit 41 performs gamma correction on each of the pieces of the RGB color component data included in the color image data based on the, for example, initial gamma tables preset as initial values.

In the gamma correction performed in the image processing unit 4, for color image data that represents a color that is close to the high-frequency color, density conversion is performed based on the individual-density conversion tables. It is thus possible to prevent show-through.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. An image processing apparatus configured to divide and read a document to generate divided image data, the image processing apparatus comprising:
an image reading unit configured to read an image of the document as color image data including a plurality of pieces of color component data;
a high-frequency-color identifying unit configured to detect a density frequency distribution for the document and identify, from a plurality of colors represented by the plurality of pieces of color component data, a high-frequency color that appears in the image of the document with a frequency satisfying a predetermined high-frequency condition;
an individual-density conversion information generating unit configured to generate, for each high-frequency color identified by the high-frequency-color identifying unit, individual-density conversion information for converting each of the pieces of color component data such that a color that is close to the high-frequency color becomes substantially the same as the high-frequency color;
a color-component-data converting unit configured to generate converted color image data by converting, based on the individual-density conversion information generated for the high-frequency color by the individual-density conversion information generating unit, each of the pieces of color component data included in color image data representing the color that is close to the high-frequency color;
the image reading unit when it divides and reads the document, the high-frequency-color identifying unit detects a density frequency distribution for the entire document and identifies, from a plurality of colors represented by the plurality of pieces of color component data, a high-frequency color that appears in the image of the entire document with a frequency satisfying a predetermined high-frequency condition;
the individual-density conversion information generating unit generates the individual-density conversion information based on the entire document; and
the color-component-data converting unit generates the converted color image data based on the entire document.

2. The image processing apparatus according to claim 1, wherein the divided image data is obtained by dividing the converted color image data based on the entire document into a plurality of pieces of image data.

3. The image processing apparatus according to claim 1, wherein the divided image data is obtained by extracting one piece of image data from part of the converted color image data based on the entire document.

4. The image processing apparatus according to claim 1, wherein the high-frequency-color identifying unit comprises:
a first-color-histogram calculating unit that calculates a first color histogram representing, when a plurality of colors represented by the plurality of pieces of color component data are divided into color groups each having a predetermined range of colors, frequencies for the respective color groups included in the image of the entire document;
a high-frequency-color-group extracting unit that extracts, based on the first color histogram calculated by the first-color-histogram calculating unit, a high-frequency color group with a frequency greater than or equal to a predetermined frequency;
a second-color-histogram calculating unit that calculates, for each high-frequency color group extracted by the high-frequency-color-group extracting unit, a second color histogram representing frequencies of respective colors included in the high-frequency color group; and
the high-frequency-color identifying unit identifies, based on the second color histogram calculated by the second-color-histogram calculating unit, a color with the greatest frequency in each high-frequency color group as a high-frequency color that satisfies the high-frequency condition.

5. The image processing apparatus according to claim 1, wherein the individual-density conversion information is a gamma table for performing gamma correction on the color component data.

6. The image processing apparatus according to claim 1, wherein the plurality of pieces of color component data are pieces of red, green, and blue image data, or pieces of cyan, magenta, and yellow image data.

7. An image forming apparatus configured to divide and read a document to generate divided image data, the image forming apparatus comprising:
an image reading unit configured to read an image of the document as color image data including a plurality of pieces of color component data;
a high-frequency-color identifying unit configured to detect a density frequency distribution for the document and identify, from a plurality of colors represented by the plurality of pieces of color component data, a high-frequency color that appears in the image of the document with a frequency satisfying a predetermined high-frequency condition;
an individual-density conversion information generating unit configured to generate, for each high-frequency color identified by the high-frequency-color identifying unit, individual-density conversion information for converting each of the pieces of color component data such that a color that is close to the high-frequency color becomes substantially the same as the high-frequency color;
a color-component-data converting unit configured to generate converted color image data by converting, based on the individual-density conversion information generated for the high-frequency color by the individual-density conversion information generating unit, each of the pieces of color component data included in color image data representing the color that is close to the high-frequency color;
the image reading unit when it divides and reads the document, the high-frequency-color identifying unit detects a density frequency distribution for the entire document and identifies, from a plurality of colors represented by the plurality of pieces of color component data, a high-frequency color that appears in the image of the entire document with a frequency satisfying a predetermined high-frequency condition;
the individual-density conversion information generating unit generates the individual-density conversion information based on the entire document; and
the color-component-data converting unit generates the converted color image data based on the entire document.

8. A method for image processing configured to divide and read a document to generate divided image data, the image processing method comprising:
reading an image of the document as color image data including a plurality of pieces of color component data;
detecting a density frequency distribution for the document and identifying, from a plurality of colors represented by the plurality of pieces of color component data, a high-frequency color that appears in the image of the document with a frequency satisfying a predetermined high-frequency condition;
generating, for each high-frequency color identified, individual-density conversion information for converting each of the pieces of color component data such that a color that is close to the high-frequency color becomes substantially the same as the high-frequency color;
generating converted color image data by converting, based on the individual-density conversion information generated for the high-frequency color, each of the pieces of color component data included in color image data representing the color that is close to the high-frequency color;
detecting when the document is divided and read, a density frequency distribution for the entire document and, identifying from a plurality of colors represented by the plurality of pieces of color component data, a high-frequency color that appears in the image of the entire document with a frequency satisfying a predetermined high-frequency condition;
generating the individual-density conversion information based on the entire document; and
generating the converted color image data based on the entire document.
